(19) United States
(12) Patent Application Publication
(10) Pub. No.: US 2021/0146554 A1
(43) Pub. Date: May 20, 2021

(54) MULTI-FINGER ROBOT APPARATUS, ELECTRONIC DEVICE MANUFACTURING APPARATUS, AND METHODS ADAPTED TO TRANSPORT MULTIPLE SUBSTRATES IN ELECTRONIC DEVICE MANUFACTURING

(71) Applicant: Applied Materials, Inc., Santa Clara, CA (US)

(72) Inventors: Jeffrey C. Hudgens, San Francisco, CA (US); Nir Merry, Mountain View, CA (US)

(21) Appl. No.: 16/807,106

(22) Filed: Mar. 2, 2020

Related U.S. Application Data
(60) Provisional application No. 62/936,180, filed on Nov. 15, 2019.

(51) Int. Cl. B25J 15/08; B25J 9/04; B25J 18/00; B25J 15/10; B25J 11/00

(52) U.S. Cl. CPC B25J 15/083; B25J 9/042; B25J 11/0095; B25J 15/106; B25J 18/00

(57) ABSTRACT

Electronic device manufacturing apparatus and robot apparatus are described. The apparatus are configured to efficiently pick and place substrates wherein the robot apparatus includes an arm component and a blade component. The blade component may comprise two or more end effectors that can retrieve and place two or more substrates at a time. The apparatus can include multiple arm components and multiple blade components. Each blade component can comprise two or more end effectors to carry two or more substrates at one time. The blade components can move independent of one another or may be dependently connected.

### RELATED APPLICATIONS

This patent application claims the benefit under 35 U.S.C. § 119(e) of U.S. Provisional Application No. 62/936,180, filed Nov. 15, 2019.

### FIELD

The present disclosure relates to electronic device manufacturing, and more specifically to apparatus and methods adapted to transport multiple substrates within an electronic device manufacturing apparatus.

### BACKGROUND

Conventional electronic device manufacturing apparatus can include multiple chambers, such as process chambers and load lock chambers. Such chambers can be included in a cluster tool where a plurality of such process and load lock chambers can be distributed about a transfer chamber. Such electronic device manufacturing apparatus can employ a robot apparatus in the transfer chamber that is configured to transport substrates between the various load lock and process chambers. In some embodiments, the transfer chamber, process chambers, and load lock chambers may operate under a vacuum at certain times. However, in certain configurations of prior art electronic device manufacturing apparatus, transport of substrates between the various chambers with the robot apparatus can be somewhat inefficient.

Accordingly, improved robot apparatus, electronic device manufacturing apparatus, and methods for transporting substrates having improved efficiency are sought.

### SUMMARY

In a first aspect a robot apparatus is provided. The robot apparatus includes a first arm rotatable about a first shoulder axis, and a first forearm rotatable relative to the first arm about a first forearm axis at a position offset from the shoulder axis. The robot apparatus further includes a first end effector attached to a distal end of the first forearm and a second end effector attached to the distal end of the first forearm. The first end effector is attached to the first forearm at a fixed position relative to the first forearm, and the second end effector is attached to the first forearm at a fixed positioned below the first end effector.

According to another aspect an electronic device processing system is provided. The electronic device processing apparatus includes a transfer chamber. The transfer chamber includes a first arm rotatable about a first shoulder axis, a first forearm rotatable relative to the arm about a first forearm axis at a position offset from the first shoulder axis, and a first wrist rotatable relative to the first forearm about a first wrist axis at a position offset from the first forearm axis. The robot arm further includes a first end effector attached to a distal end of the first wrist and a second end effector attached to the distal end of the first wrist. The first end effector is positioned above the second end effector, and the second end effector has a fixed position relative to the first end effector such that the first end effector and the second end effector are movable in unison.

In another aspect, a method of transporting multiple substrates within an electronic device manufacturing is provided. The method comprises retrieving, by a first blade comprising a first end effector and a second end effector that is beneath the first end effector and has a fixed position relative to the first end effector, a first substrate on the first end effector, wherein the first blade is attached to the robot apparatus. The method further comprises retrieving, by the first blade, a second substrate on the second end effector. The method further comprises placing, by the first blade, the first substrate from the first end effector into a process chamber. The method further comprises placing, by the first blade, the second substrate from the first end effector into the process chamber.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

FIG. 1 illustrates an above view of a substrate processing system including a robot apparatus according to one or more embodiments.

FIG. 2A illustrates a perspective view of a robot apparatus including two independently-controllable wrists each with multiple attached end effectors according to one or more embodiments.

FIG. 2B illustrates a side plan view of a robot apparatus two independently-controllable wrists each with multiple attached end effectors according to one or more embodiments.

FIG. 3A illustrates a perspective view of multiple end effectors attached to a wrist member of a robot apparatus according to one or more embodiments.

FIG. 3B illustrates a side view of multiple end effectors attached to a wrist member of a robot apparatus according to one or more embodiments.

FIG. 4A illustrates a perspective view of a robot apparatus including three independently-controllable wrists each with multiple attached end effectors according to one or more embodiments.

FIGS. 4B-4C illustrate a side view of a robot blade with a pair of end effectors and a process chamber.

FIG. 5 illustrates a perspective view of a robot apparatus with a pair of arms each with a pair of dependently controlled wrists with multiple attached end effectors on each wrist according to one or more embodiments.

FIG. 6 illustrates a perspective view of a dual robot apparatus with multiple end effectors attached to each wrist component according to one embodiment.

FIG. 7 illustrates a perspective view of a robot apparatus with two in-line extendable wrists each with multiple attached end effectors according to one or more embodiments.

FIG. 8 illustrates another flowchart depicting a method of operating a robot apparatus according to the disclosed embodiments.

FIG. 9 is a flowchart illustrating a method of transporting substrates to and from processing chambers, according to one or more embodiments.

### DETAILED DESCRIPTION

Embodiments described herein cover a robot assembly (also referred to herein as a robot apparatus) that has two or more vertically stacked end effectors. The use of the vertically stacked end effectors introduces many advantages over traditional robot assemblies. For example, vertically stacked end effectors (including a top end effector and a bottom end effector) can be implemented without increasing a footprint of a transfer chamber or a complexity of a robot assembly. Further, such robot arms with vertically stacked end effectors can dramatically increase the number of substrates that can be transferred in parallel. Such use of robot arms with vertically stacked end effectors can, for example, reduce the number of cycles that are used to fill a process chamber with substrates and/or reduce the number of cycles that are used to complete removal and replacement of processed wafers in a process chamber with unprocessed wafers. This can significantly improve the throughput and efficiency of an electronics device processing system in some use cases, such as cases in which transfer time (the time that it takes to transfer wafers into and/or out of a process chamber) is greater than process time (the time used to actually perform a process on wafers in a process chamber). In embodiments the vertical openings of substrate access ports and slit valves are increased to enable vertically stacked end effectors to be inserted into and/or through the access ports and slit valves. Additionally, wafer transfer sequences are performed in embodiments in a manner that mitigates or prevents the dropping of particles from a top end effector and/or substrate held by the top end effector onto a substrate held by the bottom end effector.

Precision and efficiency of transport of substrates between various locations in electronic device transport systems is sought. However, in some systems, transfer between the various chambers may become a bottleneck that limits efficiency. Furthermore, simplified robot construction is also sought, wherein the number of robotic arms can be minimized.

Embodiments of the present disclosure, in one aspect, provide a robot apparatus including one or more blades, wherein each blade may include multiple attached end effectors. A blade as used herein means a combination of a wrist member and at least one or two end effectors, either as separate components or as one integral component. Robot apparatus embodiments described herein include an upper arm component, and at least one blade (including multiple end effectors) coupled to the upper arm component. Each blade can therefore transport multiple substrates at one time. Thus, a refined robot construction having few arms is provided. This configuration enables not only a simplified robot construction, but may also allow enhanced efficiency.

In another aspect, an electronic device manufacturing apparatus is provided that includes a robot apparatus having one or more blades each including multiple end effectors that may be used for transporting substrates between process chambers and load lock chambers. The electronic device manufacturing apparatus includes a robot apparatus including the upper arm and at least one blade coupled to the upper arm. The blade can include at least two end effectors to transport multiple substrates at one time.

In some embodiments, the robot apparatus can include z-axis capability to enable the transport of substrates from load locks of different pitch.

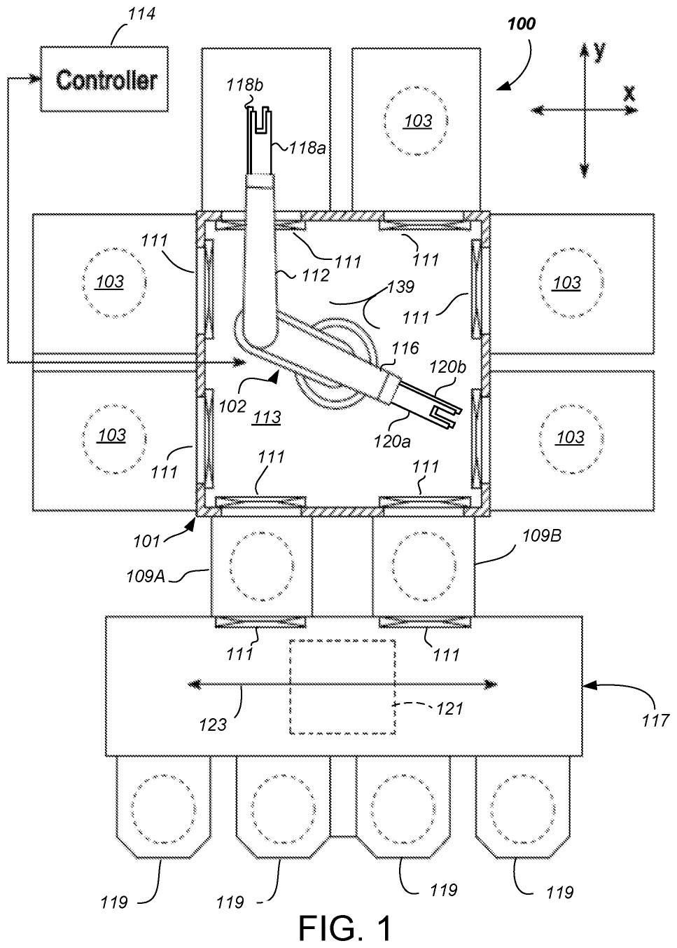

Further details and example embodiments illustrating various aspects of the robot apparatus and electronic device manufacturing apparatus are described with reference to FIGS. 1-7 herein.

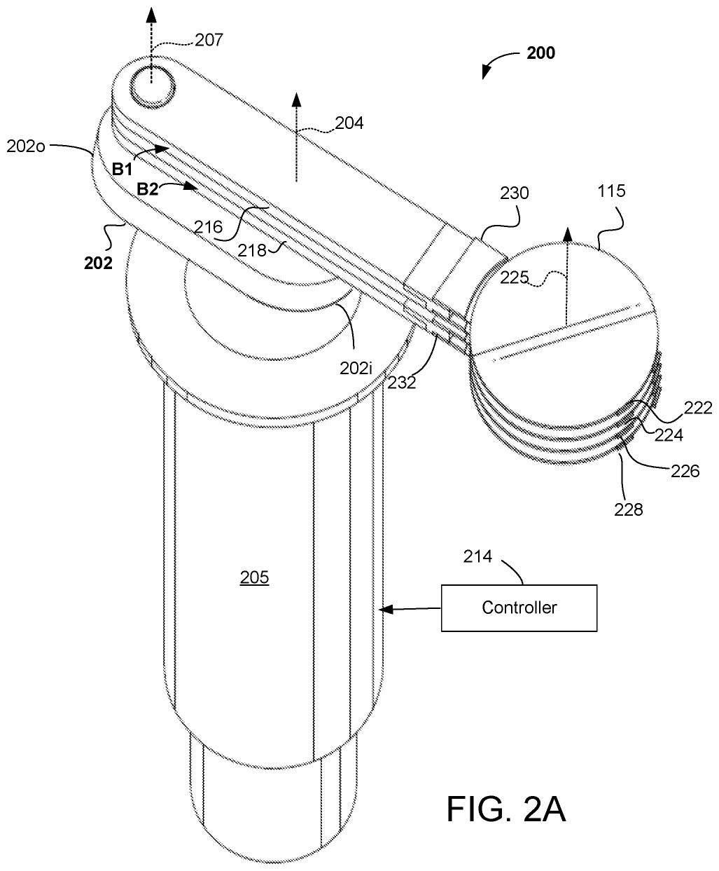

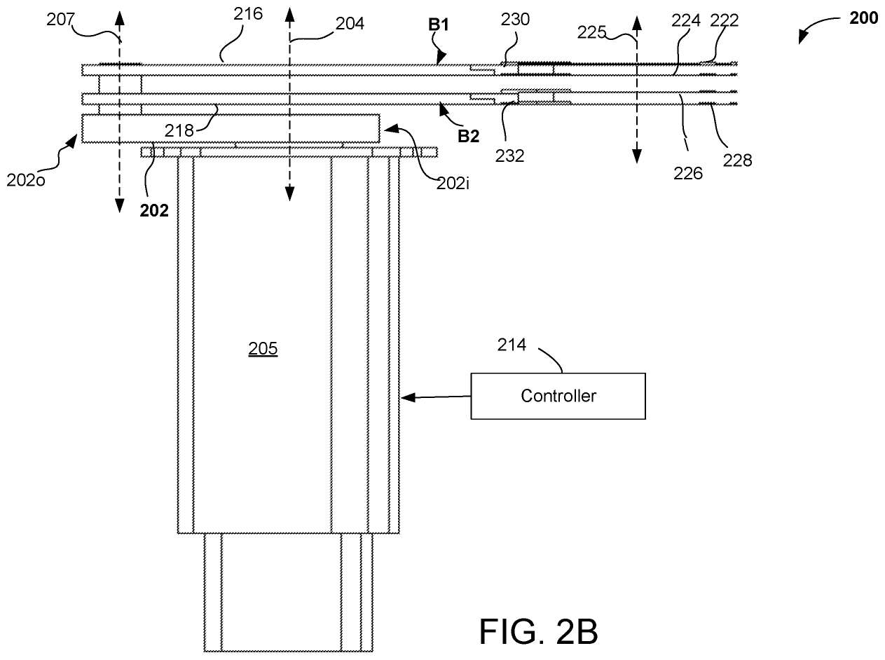

Referring now to FIG. 1, an example embodiment of an electronic device manufacturing apparatus 100 according to embodiments of the present disclosure is provided. The electronic device processing system 100 can include a mainframe 101 including the transfer chamber 113 and at least two process chambers 103. A housing of the mainframe 101 includes the transfer chamber 113 therein. The transfer chamber 113 can include top wall (not shown), bottom wall (floor) 139, and side walls. In some embodiments, the transfer chamber 113 may be maintained in a vacuum. In the depicted embodiment, a robot apparatus 102, such as depicted in FIGS. 2, 4, 5, 6, and 7 is mounted to the bottom wall (floor) 139. However, it could be mounted elsewhere, such as to the top wall (not shown—removed for clarity).

Process chambers 103 may be adapted to carry out any number of processes on the substrates 115. The robot apparatus 102 may include multi-fingered blades or arms to transport substrates 115. In the illustrated embodiment, the robot apparatus 102 includes a first arm 112 and a second arm 116. The first arm 112 includes a single blade with a pair of vertically stacked end effectors 118a, 118b. Similarly, the second arm 116 includes single blade with a pair of vertically stack end effectors 120a, 120b. As shown, a single blade or arm 112, 116 may include two vertically stacked end effectors 118a, 118b, 120a, 120b attached at the end of the blade to transport two substrates at a time. Alternatively, or additionally, a single blade or arm may include three, four or more vertically stacked end effectors. The processes can include deposition, oxidation, nitration, etching, polishing, cleaning, lithography, metrology, or the like. Other processes may be carried out, as well. The load lock apparatus 109A, 109B may be adapted to interface with a factory interface 117 or other system component, that may receive substrates 115 from substrate carriers 119 (e.g., Front Opening Unified Pods (FOUPs)) that can be docked at load ports of the factory interface 117, for example. A load/unload robot 121 (shown dotted) may be used to transfer substrates between the substrate carriers 119 and the load lock apparatus 109A, 109B. Transfers of substrates may be carried out in any sequence or direction. Load/unload robot 121 may be similar to the robot apparatus 102 in some embodiments, but may include a mechanism to allow the robot apparatus to move laterally in either lateral direction and indicated by arrow 123. In one embodiment, robot apparatus 102 is configured to operate in vacuum, while load/unload robot 121 may not be configured to operate in vacuum. Any other suitable robot can be used. As shown, transfers may occur through slit valves 111 and the substrates may be retrieved, and or deposited, from or to load lock apparatus 409A and 409B.

FIG. 2A illustrates a perspective view of a robot apparatus 200 including two independently-controllable wrists 216, 218 each with multiple attached end effectors according to one or more embodiments. Wrist 216 includes end effectors 222, 224. Wrist 218 includes end effectors 226, 228. FIG. 2B illustrates a side plan view of the robot apparatus 200 having two independently-controllable wrists each with multiple attached end effectors according to one or more embodiments.

In an embodiment, robot apparatus 200 corresponds to robot apparatus 102 of FIG. 1. In such an embodiment, the robot apparatus 200 may be configured and adapted to transfer substrates 115 between various process chambers 103, and/or to exchange substrates 115 at one or more load lock apparatus 109A, 109B, for example. In the depicted embodiment of FIG. 1, two load lock apparatus 109A, 109B are shown. However, the robot apparatus 200 could be used with only one load lock apparatus or more than two load lock apparatus.

The robot apparatus 200 has an upper arm 202 including an inboard end 202i and outboard end 202o. The inboard end 202i is configured to be rotatable about a shoulder axis 204 by an upper arm drive motor of a drive motor assembly 205. A drive assembly of driving and driven pulleys and transmission members is included within the upper arm 202.

The robot apparatus 200 shown includes two blades B1 (upper), and B2 (lower) coupled for rotation to the outboard end 202o of the upper arm 202 opposite from the inboard end 202i. Each of the blades B1 and B2 is independently rotatable about the outboard axis 207 through the commanded action of a first drive motor, and a second drive motor, respectively. Each of the first drive motor and second drive motor is commanded by a suitable control signal received from a controller 214. Controller 214 can be any suitable processor, memory, electronics and/or drivers capable of processing control instructions and carrying out motion of the upper arm 202 and blades B1 and B2.

The upper arm 202 can have a center-to-center length of L1, wherein the centers of the length L1 are the shoulder axis 204 and the outboard axis 207. Each of the blades B1 and B2 in the depicted embodiment can be made up of a wrist member, namely first wrist 216 and second wrist 218. Further, each of the blades B1 and B2 in the depicted embodiment includes at least two end effectors, namely first end effector 222, second end effector 224, third end effector 226, and fourth end effector 228 that are each configured and adapted to support and transport a substrate 115 thereon.

The blades B1 and B2 each have a center-to-center length L2 wherein the centers of the length L2 for the blades B1 and B2 are the outboard axis 204 and a nominal center 225 of a substrate support location that is configured to support substrates 115 on each of end effectors 222, 224, 226, and 228. The nominal center 225 is where the substrate 115 will rest on each of the first, second, third, and fourth end effectors 222, 224, 226, and 228 when nominally positioned thereon, as depicted. Restraining features restrain location of the substrates on the end effectors 222, 224, 226, and 228 within limits. In the depicted embodiment, the first and second wrist members 216 and 218, and the end effectors 222, 224, 226, and 228 are separate interconnected members. However, it should be understood that each wrist member and end effector may be integrally formed in some embodiments and constitute one unitary component. In the depicted embodiment, each of the wrist members 216 and 218 may include an orientation adjuster 230 and 232 at the end thereof to allow for fine orientation adjustments (e.g., adjustments for droop and/or tilt) to each of the end effectors 222, 224, 226, and 228. The orientation adjusters 230 and 232 can use screws and/or shims to accomplish end effector attitude adjustments.

Thus, it should be apparent that the first blade B1 is configured for independent rotation relative to the upper arm 202 about the outboard axis 207, and wherein the first blade B1 includes the first end effector 222 and the second end effector 224. The first end effector 222 may be fixed to the wrist member 216 directly above the second end effector 224, which is also fixed to the wrist member 216. Likewise, the second blade B2 is configured for independent rotation relative to the upper arm 204 about the outboard axis 207, and wherein the second blade B2 includes a third end effector 226 and a fourth end effector 228. The third end effector 226 may be fixed to the wrist member 218 directly above the fourth end effector 228, which is also fixed to the wrist member 218. The rotation is provided by the drive motor assembly 205 and the drive assembly described below.

As can be seen in FIGS. 2A-2B, the first end effector 222, second end effector 224, third end effector 226, and fourth end effector 228 lie one above another when configured in a folded and zeroed configuration (e.g., in a vertically stacked configuration), as shown. This folded and zeroed configuration is the neutral configuration and the blades B1 and B2, can be rotated approximately +/−170 degrees from this orientation, for example.

As depicted, end effectors 222 and 224 may be attached to wrist 216, one above the other. The end effectors may be separately attached components or may be a single component attached to the wrist 216 as a single end effector component with multiple fingers. Similarly, end effectors 226 and 228 may be attached to wrist 218, one directly above the other to provide for transport of multiple substrates 115 at a time. Though the blades B1 B2 are each shown with two end effectors 222, 224 and 226, 228, respectively, the blades B 1, B2 can alternatively have other numbers of end effectors. For example, B1 may have three vertically stacked end effectors, and B2 may additionally have three vertically stacked end effectors.

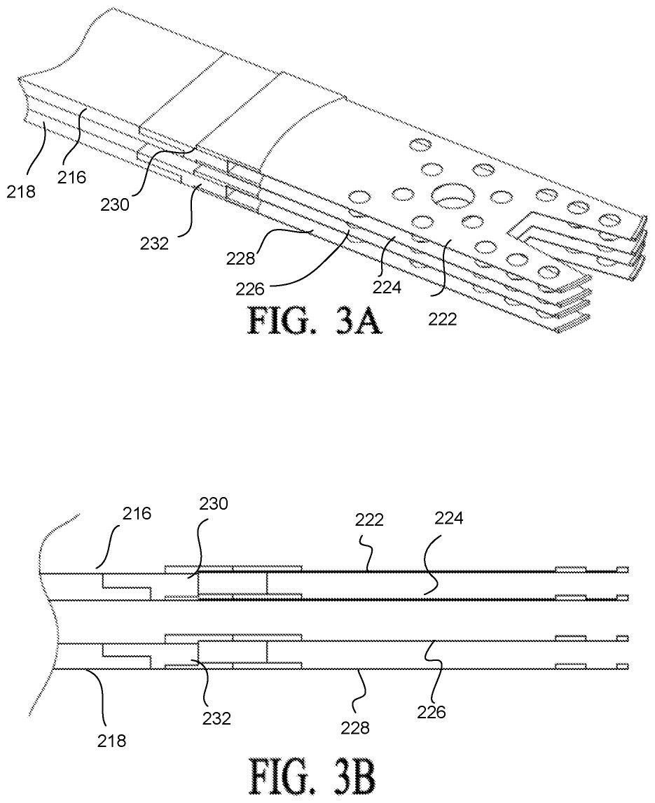

FIG. 3A and 3B illustrate an embodiment including two wrist members 216, 218 and four end effectors 222, 224, 226, 228, each wrist member 216, 218 including two end effectors. However, any number of end effectors may be attached to each wrist member. Each of the pairs (or triplets or quadruplets, for example) of end effectors may be independently rotatable and/or extendable. As shown in FIG. 3B, the dual end effectors 222 and 224 are shown connected to the first wrist member 216 by orientation adjuster 230. The same construction is used for dual end effectors 226 and 228 attached to second wrist member 218 by orientation adjuster 232. The drive motor assembly 205 and the blade drive assembly can be the same as described before for FIGS. 2A-B. This embodiment provides increased put and get capability and thus enhanced efficiencies, where a put is placement of a substrate at a load lock or process chamber, and where a get is retrieval of a substrate from a load lock or process chamber.

A load lock apparatus may include, for example, two or four substrate support locations per load lock. One suitable put and get sequence that can be carried out by robot apparatus 200 to unload a pair of processed wafers from a process chamber and to load the process chamber with unprocessed wafers is, for example:
Dual GET from a load lock by end effectors 222, 224 (2 substrates 115 picked up),
End effectors 226, 228 carry no substrates initially,
GET from process chamber by end effector 226,
PUT into process chamber by end effector 224,
GET from process chamber by end effector 228,
PUT into process chamber by end effector 222, and
Dual PUT in the load lock (or another load lock) by end effectors 226, 228 (2 substrates 115).

Another possible sequence that can be carried out by the robot apparatus 200 is:
Dual GET from a first load lock by end effectors 226, 228 (2 substrates 115 picked up),
End effectors 222, 224 carry no substrates initially,
GET from process chamber by end effector 222,
PUT into process chamber by end effector 228,
GET from process chamber by end effector 224,
PUT into process chamber by end effector 226, and
Dual PUT in the first load lock (or another load lock) by end effectors 222, 224 (2 substrates 115).

If the process chamber is a twin chamber that processes two wafers at a time, then the above described sequences of get and put operations may be used to completely unload and load the twin chamber in a single cycle. By contrast, a conventional robot apparatus with only a single end effector per blade/wrist would perform additional cycles, and thus additional movements of the robot arms to complete the same transfer. For example, the two blades might each perform a get operation to retrieve two processed wafers from the process chamber, then move the robot arm to the load lock and perform two put operations, then perform two get operations from the load lock, then move the robot arm to perform two put operations into the process chamber.

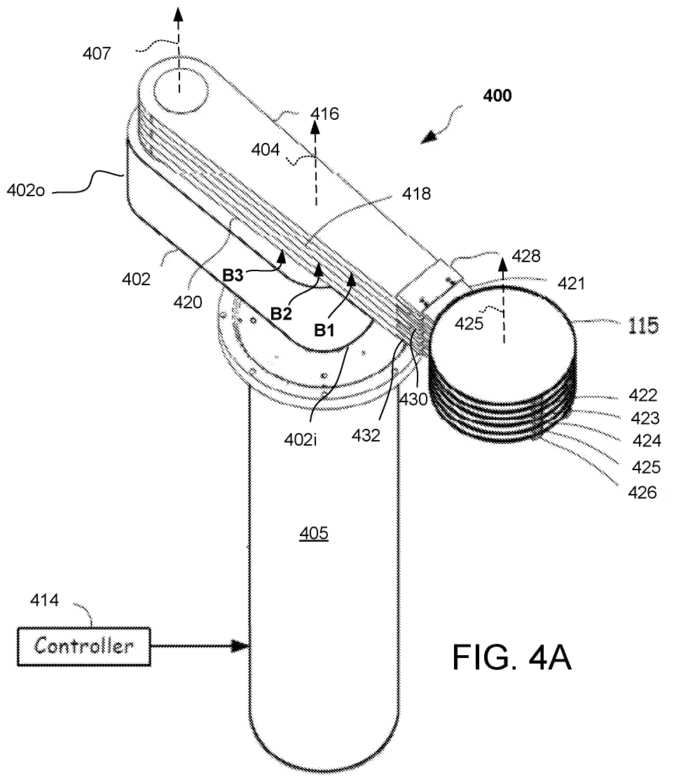

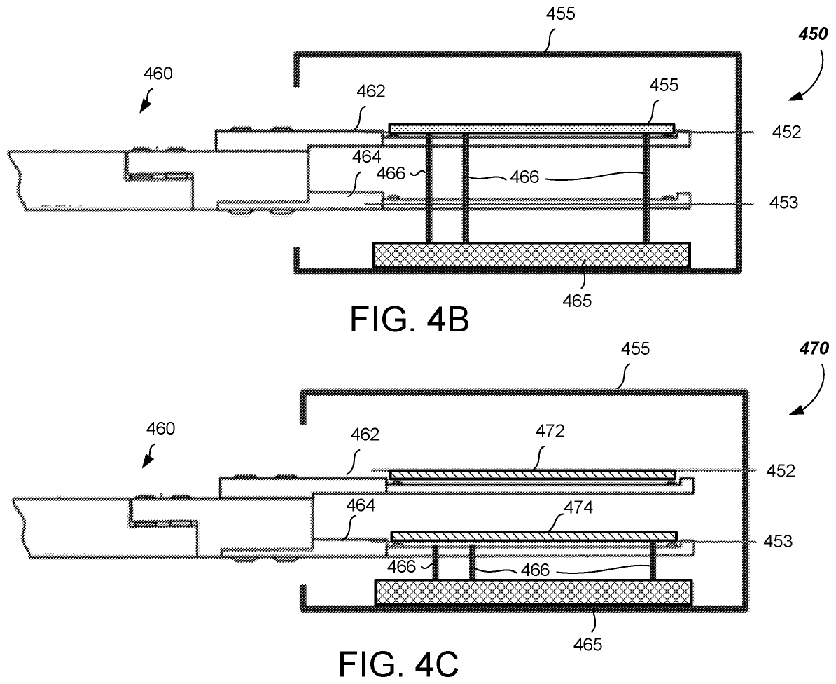

Referring now to FIG. 4A, a robot apparatus 400 is shown that includes three independently driven wrist members/blades B1, B2, B3, each of which includes two end effectors 421-426. The robot apparatus 400 may be configured and adapted to transfer substrates 115 between various process chambers 103, and/or to exchange substrates 115 at one or more load lock apparatus 109A, 109B, for example.

The robot apparatus 400 has an upper arm 402 including an inboard end 402i and outboard end 402o. The inboard end 402i is configured to be rotatable about a shoulder axis 404 by an upper arm drive motor of a drive motor assembly 405. A drive assembly of driving and driven pulleys and transmission members is included within the upper arm 402 as will be apparent from the following.

The robot apparatus 400 shown includes three blades B1 (upper), B2 (middle), and B3 (lower) coupled for rotation to the outboard end 402o of the upper arm 402 opposite from the inboard end 402i. Each of the blades B1, B2, B3 is independently rotatable about the outboard axis 407 through the commanded action of a first drive motor, a second drive motor, and a third drive motor, respectively. Each of the first drive motor, second drive motor, and third drive motor is commanded by a suitable control signal received from a controller 414. Controller 414 can be any suitable processor, memory, conditioning electronics and drivers capable of processing control instructions and carrying out motion of the upper arm 402 and blades B1, B2, B3.

The upper arm 402 can have a center-to-center length of L1, wherein the centers of the length L1 are the shoulder axis 404 and the outboard axis 407. Each of the blades B1, B2, B3 in the depicted embodiment can be made up of a wrist member, namely first wrist member 416, second wrist member 418, and third wrist member 420. Further, each of the blades B1, B2, B3 in the depicted embodiment includes at least two end effectors, namely first end effector 421, second end effector 422, third end effector 423, fourth end effector 424, fifth end effector 425, and sixth end effector 426 that are each configured and adapted to support and transport a substrate 115 thereon.

The blades B1, B2, B3 each have a center-to-center length L2, wherein the centers of the length L2 of the blades B1, B2, and B3 are the outboard axis 404 and a nominal center 425 of a substrate support location that is configured to support substrates 115 on each of end effectors 421, 422, 423, 424, 425, and 426. The nominal center 425 is where the substrate 115 will rest on each of the first, second, third, fourth, fifth, and sixth end effectors 421, 422, 423, 424, 425, 426 when nominally positioned thereon. Restraining features restrain location of the substrates on the end effectors 421, 422, 423, 424, 425, 426 within limits. In the depicted embodiment, the first, second, and third wrist members 416, 418, 420 and the end effectors 421, 422, 423, 424, 425, 426 are separate interconnected members. However, it should be understood that each wrist member and end effector may be integrally formed in some embodiments and constitute one unitary component. In the depicted embodiment, each of the wrist members 416, 418, 420 may include an orientation adjuster 428, 430, 432 at the end thereof to allow for fine orientation adjustments (e.g., adjustments for droop and/or tilt) to each of the end effectors 421, 422, 423, 424, 425, 426. The orientation adjusters 428, 430, 432 can use screws and/or shims to accomplish end effector attitude adjustments.

Thus, it should be apparent that the first blade B1 is configured for independent rotation relative to the upper arm 402 about the outboard axis 407, and wherein the first blade B1 includes the first and second end effectors 421 and 422. Likewise, the second blade B2 is configured for independent rotation relative to the upper arm 404 about the outboard axis 407, and wherein the second blade B2 includes a third and fourth end effector 423 and 424. Moreover, the third blade B3 is configured for independent rotation relative to the upper arm 102 about the outboard axis 107, and wherein the third blade B3 includes the fifth and sixth end effectors 425 and 426. The rotation is provided by the drive motor assembly 405 and the drive assembly described below.

As can be seen in FIG. 4A, the first end effector 421, second end effector 422, third end effector 423, fourth end effector 424, fifth end effector 425, and sixth end effector 426 lie one above another when configured in a folded and zeroed configuration, as shown. This folded and zeroed configuration is the neutral configuration and the blades B1, B2, B3, can be rotated approximately +/−170 degrees from this orientation, for example.

A load lock apparatus may include, for example, two or four substrate support locations per load lock. The load lock apparatus is a heated load lock apparatus that includes one or more heating elements to heat substrates in an embodiment. One suitable put and get sequence that can be carried out by robot apparatus 400 to unload a set of four processed wafers from a quad process chamber and to load the quad process chamber with four unprocessed wafers is, for example:
Dual GET from a load lock by end effectors 421 and 425 (2 substrates 115 picked up),
Dual GET from a load lock by end effectors 422 and 426 (2 substrates 115 picked up),
End effectors 423, 424 carry no substrates initially,
GET from process chamber by end effector 423,
PUT into process chamber by end effector 422,
GET from process chamber by end effector 424,
PUT into process chamber by end effector 421,
GET from process chamber by end effector 421,
PUT into process chamber by end effector 426,
GET from process chamber by end effector 422,
PUT into process chamber by end effector 425,
Dual PUT in the load lock (or another load lock) by end effectors 421, 422 (2 substrates 115); and
Dual PUT in the load lock (or another load lock) by end effectors 423, 424 (2 substrates 115).

In some embodiments, the robot apparatus 400 includes additional wrist members and end effectors. For example, the robot apparatus 400 includes a fourth wrist member rotatable about outboard axis 407 in an embodiment. A seventh end effector and an eighth end effector are attached to the distal end of the fourth wrist member in an embodiment. The eighth end effector are below the seventh end effector and have a fixed position relative to the seventh end effector in an embodiment. The fourth wrist member is independently rotatable about the outboard axis 407 in an embodiment. The robot apparatus 400 also includes a fifth wrist member rotatable about outboard axis 407 in an embodiment. A ninth end effector and a tenth end effector are attached to the distal end of the fifth wrist member in an embodiment. The tenth end effector is below the ninth end effector and has a fixed position relative to the ninth end effector in an embodiment. The fifth wrist member is independently rotatable about the outboard axis 407 in an embodiment. Additionally, more than two end effectors are attached to the wrist members in some embodiments. Any number of end effectors may be attached to the wrist members. For example, three, four or five end effectors may be attached to the distal end of each wrist member.

FIGS. 4B-4C illustrate a side view of a robot blade 460 with a pair of end effectors 462, 464 and a process chamber 455. The robot blade 460 may correspond to any of robot blades 216, 218, 416, 418, 420 described earlier, or other robot blades with pairs of vertically offset end effectors. The process chamber 455 includes a substrate receiving area 465 that includes a set of lift pins 466. The lift pins 466 may raise and lower to two different substrate transfer heights (also referred to as pitches) 452, 453. A first substrate transfer height 453 may be used for placing substrates on a lower end effector 464 and removing substrates from the lower end effector 464, and a second substrate transfer height may be used for placing substrates on an upper end effector 462 and for removing substrates from the upper end effector 462.

FIG. 4B shows removal of a processed wafer 455 from the process chamber 455 by blade 460. In one embodiment, if both end effectors 462, 464 are empty, then a processed wafer 455 is first placed on the upper end effector 462 at the upper substrate transfer height 452. A next processed wafer (not shown) is then placed on the lower end effector 464 at the lower substrate transfer height 453. This may minimize particles from one substrate falling on another substrate. In embodiments, process chamber 455 includes a carousel and multiple substrate pockets. Once substrate 455 is removed from process chamber 455, the carousel may rotate and an additional processed wafer may be positioned near a chamber port that is accessible by the blade 460, and the additional processed wafer may be placed on the lower end effector 464.

FIG. 4C shows placement of a substrate 474 that has not yet been processed by process chamber 455 (referred to as an unprocessed substrate) from lower end effector 464 onto the lift pins 466 at lower substrate transfer height 453. The upper end effector 462 may also contain another unprocessed substrate 472 on upper end effector 472. In embodiments, if the blade 460 contains two unprocessed substrates 472, 474, then the unprocessed substrate 474 on the lower end effector 464 is first placed into process chamber 455, followed by placement of the unprocessed substrate 472 on the upper end effector 462. This sequence can further mitigate particle contamination onto substrate 474.

Furthermore, in instances in which unprocessed substrates are placed into the process chamber 455 and processed substrates are removed from the process chamber 455, by first placing from the lower end effector 464, and then retrieving a processed substrate from the lower end effector 464 while the upper end effector 462 still holds an unprocessed substrate further reduces particle contamination on the substrates held on the lower end effector 464.

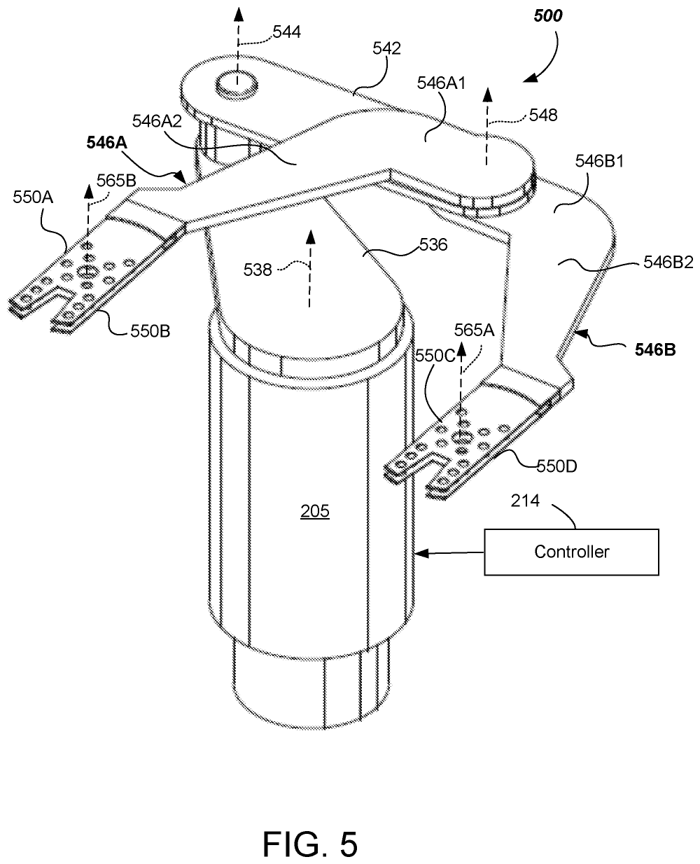

FIG. 5 illustrates a perspective view of a robot apparatus 500 according to disclosed embodiments. Robot apparatus 500 includes an arm 536 that rotates about a first rotational axis 538. A forearm 542 may be attached to a distal end of the arm 536 such that it rotates about a second rotational axis 544. Two wrist members 546A, 546B may be attached to a distal end of the shoulder 542 such that they each rotate about a third rotational axis 548. A first wrist member 546A may be positioned above the forearm 542, and a second wrist member 546B may be positioned beneath the forearm 542. The first wrist member 546A and the second wrist member 546B may be L-shaped. The first wrist member 546A may include a first leg 546A1 and a second leg 546A2. The first leg 546A1 may be rotatably coupled to the forearm 542 about the third rotational axis 548 at a rotation point. The second leg 546A2 may be longer than the first leg 546A1 and may be coupled to a first end effector 550A and a second end effector 550B that is beneath the first end effector 550A.

The second wrist member 546B may include a first leg 546B1 and a second leg 546B2. The first leg 546B1 may be rotatably coupled to the forearm 542 about the third rotational axis 548 at the rotation point. The second leg 546B2 may be longer than the first leg 546B1 and may be coupled to a third end effector 550C and a fourth end effector 550D. The second leg 546B2 may be longer than the first leg 546B1 and may be coupled to a third end effector 550C and a fourth end effector 550D that is beneath the third end effector 550C.The first leg 546B1 may include a bend that provides for the vertical alignment of the first and third end effectors 550A and 550C, and the second and fourth end effectors 550B and 550D. Thus the third and fourth end effectors 550C, 550D may be positioned beneath the first and second end effectors 550A, 550B.

In an alternative embodiment, the robot apparatus 500 may be simplified such that first wrist member 546A and second wrist member 546B are part of a single combined U-shaped wrist member. Accordingly, the relative position of first wrist member 546A and second wrist member 546B would be fixed, and would rotate together about third rotational axis 548. Such a configuration achieves the same motion to unload/reload a twin process chamber in one cycle but with fewer motion axes as compared to robot apparatus 500.

The embodiment of the robot apparatus 500 shown in FIG. 5 may be adapted for use in the substrate processing system 100 of FIG. 1. In operation, the arm 536 may be rotated so as to position the end effectors 550A-D adjacent a target destination (e.g., a process chamber 103 or a load lock chamber 109A-B) to pick or place a substrate 115. The arm 536 and the forearm 542 then may be suitably actuated (e.g., rotated) to extend the first wrist member 546A and the second wrist member 546B to or from the target destination. As the first wrist member 546A and the second wrist member 546B move from the first rotational axis 538, the first wrist member 546A and the second wrist member 546B may rotate in opposite directions about the third rotational axis 548. The center of the nominal substrate placement locations on the first and second end effectors 550A-B and the third and fourth end effectors 550C-D may be separated by a first distance, which may be dependent on a second distance between end effectors 550A-D and the first rotational axis 238.

The first blade including the first and second end effector 550A, 550B and the second blade including the third and fourth end effectors 550C, 550D may be inserted into a process chamber (e.g., 103) simultaneously through a multi-slit valve (e.g., a dual slit valve) in a straight line manner, i.e., inserted in a direction substantially perpendicular to a facet or side of a process chamber 103. While passing through the dual slit valves, the first and second end effectors 550A, 550B and the third and fourth end effectors 550C, 550D may be at a first pitch that provides for the first separation distance between nominal substrate placement centers of the first and third end effectors 550A, 550C (and second and fourth end effectors 550B and 550D). This first separation distance may match an opening offset distance of the dual slit valves. Note that each slit valve of the dual slit valve may be a double height slit valve that is sized to accept two vertically stacked end effectors (e.g., end effectors 550A, 550B).

Once through the dual slit valves, the first and third end effectors 550A, 550C (and second and fourth end effectors 550B, 550D) may be rotated apart about the third rotational axis 548 to a second pitch that provides for a second separation distance between the nominal substrate placement centers of the first and third end effectors 550A, 550C (and second and fourth end effectors 550B and 550D). For example, the first wrist member 546A and the second wrist member 546B may rotate about the third rotational axis 548. The second separation distance may match a processing distance between dual processing locations within a process chamber 103, which is wider than the distance between the dual slit valves.

Similarly, the end effectors 550A-D may be inserted simultaneously into the load lock chamber 109A-B (FIG. 1) through the slit valves (which may be double height dual slit valves) in a straight line manner. While passing through the slit valves, the end effectors 550A-D may be at the first pitch. For example, the distance between end effectors 550A and 550C may have a first value. Once through the slit valves, the first and second end effectors 550A, 550C may remain at the first pitch or be rotated outward to the second pitch. For example, the first wrist member 546A and the second wrist member 546B may rotate about the third rotational axis 548 to a second value for the distance between end effectors 550A and 550C. The second value of the distance may be selected to be approximately a same separation distance between centers of dual transfer locations within the load lock chamber 109A-B. The processes described above may be applied in reverse order as the first end effector 550A and the second end effector 550B are retracted from a process chamber 103 or the load lock chamber 109A-B.

The substrate processing system 500 may be described by the first wrist member 546A and the second wrist member 546B configured to rotate the first and third end effectors 550A, 550C to a first pitch providing for a first end effector distance between the first end effector 550A and the third end effector 550C while at an initial distance from the first rotational axis 538. The first wrist member 546A and the second wrist member 546B may rotate in opposite directions to a second pitch providing for a second end effector distance between the first end effector 550A and the third end effector 550C while at an extended distance from the first rotational axis 538. Accordingly, the distance between end effectors 550A and 550C may be dependent on a distance the wrist members are extended and kinematically determined by cams in the robot apparatus 500 that are part of a pulley system that drives wrist members 546A, 546B.

In some embodiments, the robot apparatus 500 may include additional forearm members, wrist members and end effectors to provide the ability to transport additional substrates. For example, the robot apparatus may include a third forearm rotatable relative to the arm 536 about the forearm axis 544. A third and fourth wrist member may be rotatable relative the third forearm member about a second wrist axis. A fifth end effector and sixth end effector may be attached to the distal end of the third wrist member and a seventh and eight end effector may be attached to the distal end of the fourth wrist member. The sixth end effector may be below the fifth end effector and may have a fixed position relative to the fifth end effector. Similarly, the eighth end effector may be below the seventh end effector and may have a fixed position relative to the seventh end effector. The third and fourth wrist members may be dependently rotatable about the second wrist axis. When in a retracted position, the third wrist member may be positioned directly under the first wrist member and the fourth wrist member may be positioned directly under the second wrist member. The third and fourth wrist members may be configured to provide a first distance between the distal ends of the third and fourth wrist members when retracted and the same distance, or a second distance, between the distal ends when extended.

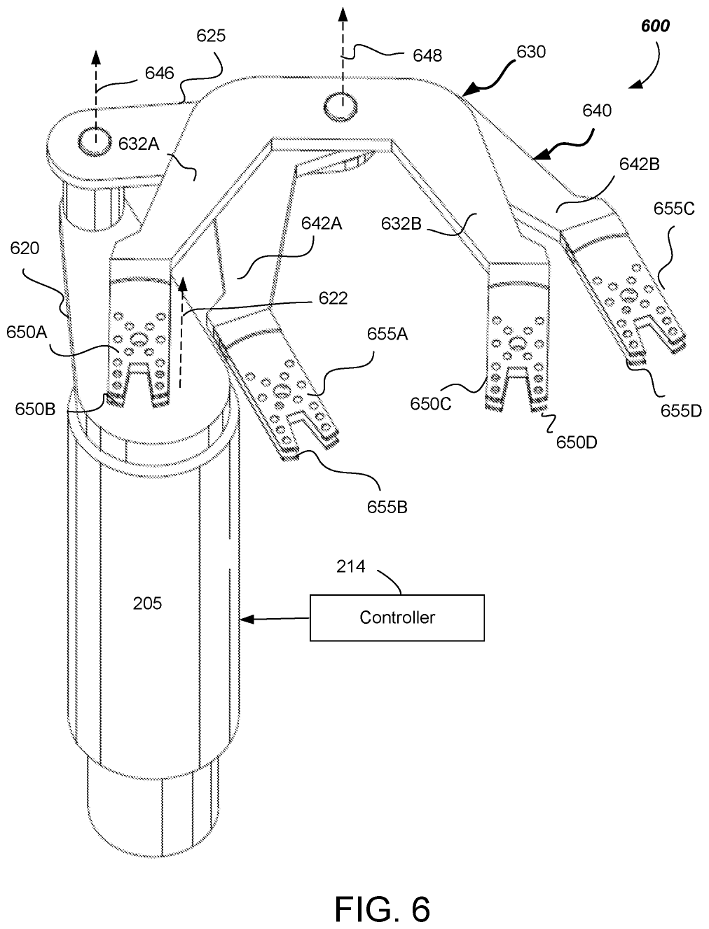

FIG. 6 depicts another example of a robot apparatus 600 with multi-finger end effectors. Robot apparatus 600 includes an arm 620 that rotates about a first rotational axis 622. A forearm 625 may be attached to a distal end of the arm 620 such that it rotates about a second rotational axis 646. Two twin wrist members 630 and 640 may be attached to a distal end of the forearm 625 such that they each rotate about a third rotational axis 648. The first twin wrist member 630 may be positioned above the second twin wrist member 640. The first twin wrist member 630 and the second twin wrist member 640 may be U-shaped. The first twin wrist member 630 may include a first leg 632A and a second leg 632B. A first and second end effector 650A-B may be attached to the distal end of the first leg 632A and a third and fourth end effector 650C-D may be attached to the distal end of the second leg 632B. The second twin wrist member 640 may also include a first leg 642A and a second leg 642B. A fifth and sixth end effector 655A-B may be attached to the distal end of the first leg 642A. A seventh and eighth end effector 655C-D may be attached to the distal end of the second leg 642B.

The first and second twin wrist member 630 and 640 may be independently rotatable about axis 648 to retrieve and place substrates to and from a source location to a destination location. In some embodiments, each of the twin wrist members 630 and 640 can perform a dual GET and PUT, a quadruple GET and PUT operation, or an 8 substrate GET and PUT operation using the four end effectors attached to each leg of the twin wrist members 630 and 640. In another embodiment, the twin wrist members may be attached to two different, independently rotatable forearms. Therefore, the first twin wrist member 630 and the second twin wrist member 640 may be movable about axis 646 independent of one another. In other embodiments, the robot apparatus 600 may include additional twin wrist members (e.g., 3, 4, 5, etc.).

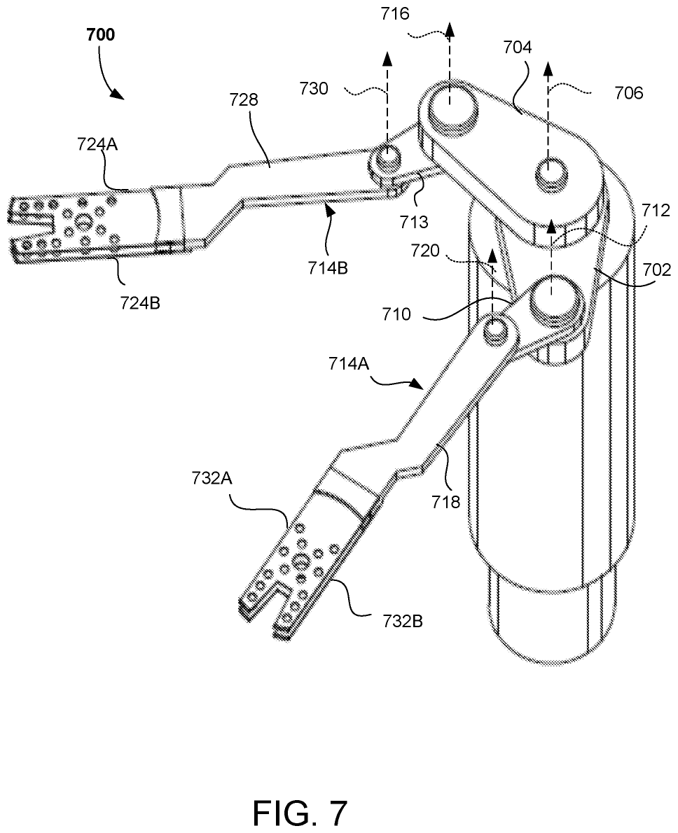

FIG. 7 depicts another example of a robot apparatus 700 with multi-finger end effectors (i.e. vertically stacked end effectors). The robot 700 includes a first arm assembly 714A and a second arm assembly 714B. The first arm assembly 714A may include a first upper arm 702 and the second arm assembly 714B may include a second upper arm 704. Both the first upper arm 702 and the second upper arm 704 may be substantially rigid cantilever beams including forearm drive assembly components therein. The second upper arm 704 is spaced vertically above the first upper arm 702 and they are independently rotatable about a shoulder axis 706. In another aspect, the first upper arm 702 and the second upper arm 704 may be configured and adapted to be simultaneously rotated about a shoulder axis 706 (e.g., a first axis) relative to a motor housing in clockwise and counterclockwise rotational directions. Rotation of the first upper arm 702 and the second upper arm 704 may be accomplished by a first motor and third motor located within the motor housing, as commanded by the controller 114. When in a fully-retracted orientation, the first arm assembly 714A and second arm assembly 714B can be rotated to a new position along with synchronous and/or dependent rotation of a second motor. In another example, the first arm assembly and second arm assembly can be asynchronously rotatable. For example, the movement of the first upper arm, and thus the first arm assembly, can be independent of the movement of the second upper arm and second arm assembly.

The shoulder axis 706 may be stationary in a vertical direction. This embodiment of the robot 700 may not include Z-axis capability and may be used with lift pins, moving platforms, or other like moveable substrate support structure in the process chambers 103 and/or load lock chambers 109A-B (FIG. 1) to accomplish substrate exchanges. However, other embodiments of the robot 700 may include another motor and vertical drive assembly to accomplish Z-axis capability, wherein such Z-axis or vertical drive assemblies are known.

The first arm assembly 714A includes a first forearm 710 mounted and rotatably coupled to the first upper arm 702 at a second axis 712. The second axis 712 is spaced from the shoulder axis 706. The first forearm 710 is configured and adapted to be rotated in an X-Y plane relative to the first upper arm 702 about the second axis 712. Rotation of the first forearm 710 about the second axis 712 may be dependent on the rotation of the first upper arm 702 about the shoulder axis 706. The first forearm 710 may be vertically located between the first upper arm 702 and the second upper arm 704.

The second arm assembly 714B includes a second forearm 713 mounted and rotatably coupled to the second upper arm 704 at a third axis 716. The third axis 716 is spaced from the shoulder axis 706. The second forearm 713 is configured and adapted to be rotated in the X-Y plane relative to the second upper arm 704 about the third axis 716. Rotation of the second forearm 713 about the third axis 716 may be dependent on the rotation of the second upper arm 704 about the shoulder axis 706. The second forearm 713 may be vertically located between the first upper arm 702 and the second upper arm 704.

The first forearm 710 and second forearm 713 are configured and adapted to be rotated in either a clockwise or counterclockwise rotational direction about the second axis 712 and the third axis 716, respectively. Rotation may be +/− about 140 degrees. The first forearm 710 and second forearm 713 are located at different vertical locations between the first upper arm 702 and the second upper arm 704 and do not interfere with one another when being independently rotated via rotation of the first upper arm 702 and/or the second upper arm 704.

The first arm assembly 714A includes a first wrist member 718 mounted and rotatably coupled to the first forearm 710 at a fourth axis 720. The fourth axis 720 is spaced from the second axis 712. The first wrist member 718 is configured and adapted to be rotated in an X-Y plane relative to the first forearm 710 about the fourth axis 720. Rotation of the first wrist member 718 about the fourth axis 720 may be dependent on the rotation of the first forearm 710 about the second axis 712. The first wrist member 718 may be vertically located between the first upper arm 702 and the second upper arm 704.

The first wrist member 718 may be coupled to a first end effector 732A and to a second end effector 732B that is below the first end effector 732A. In some embodiments, the first wrist member 718 and the first and second end effectors 732A, 732B may be integral with one another, i.e., from a same piece of material. The first and second end effectors 732A, 732B may be configured to carry and transport substrates 115.

Rotation of first wrist member 718, and thus the first and second end effectors 732A, 732B, may be imparted by a first wrist member drive assembly. The first wrist member 718 may be configured and adapted for rotation relative to the first forearm 710 in either a clockwise or counterclockwise rotational direction about the fourth axis 720 by the first wrist member drive assembly. Rotation may be +/− about 70 degrees. In particular, relative rotation between the first forearm 710 and the first upper arm 702 causes the first wrist member 718, coupled first and second end effectors 732A, 732B, and supported first and second substrates, to translate along a first path in an approximately first radial direction. Such translation may be into one of the process chambers 103 as shown in FIG. 1, for example. However, it should be understood that the first wrist member drive assembly may be configured to include cammed pulleys that are configured to carry out a first path that is other than a purely radial path, such as a sweeping path.

The second arm assembly 714B includes a second wrist member 728 mounted and rotatably coupled to the second forearm 713 at a fifth axis 730. The fifth axis 730 is spaced from the third axis 716. The second wrist member 728 is configured and adapted to be rotated in an X-Y plane relative to the second forearm 713 about the fifth axis 730. Rotation of the second wrist member 728 about the fifth axis 730 may be dependent on the rotation of the second forearm 713 about the third axis 716. The second wrist member 728 may be vertically located between the first upper arm 702 and the second upper arm 704.

The second wrist member 728 may be coupled to a third end effector 724A and to a fourth end effector 724B that is below the third end effector 724A. In some embodiments, the second wrist member 728 and the third and fourth end effectors 724A, 724B may be integral with one another, i.e., from a same piece of material. The third and fourth end effectors 724A, 724B may be configured to carry and transport substrates 115.

Translation of the second wrist member 728, and thus the third and fourth end effectors 724A, 724B and supported substrates, may be imparted by a second wrist member drive assembly. The second wrist member 728 is configured and adapted for rotation relative to the second forearm 713 in either a clockwise or a counterclockwise rotational direction about the fifth axis 730 by the second wrist member drive assembly. Rotation may be +/− about 70 degrees. In particular, relative rotation between the second forearm 713 and the second upper arm 704 can cause the second wrist member 728 and coupled third and fourth end effectors 724A, 724B as well as the supported substrates to translate substantially radially along a second path. Such translation may be into one of the process chambers 110 as shown in FIG. 1, for example. In another example, the process chambers 110 can be configured radially about the robot apparatus 700, rather than rectangular as depicted in FIG. 1. However, it should be understood that the second wrist member drive assembly may be configured to include cammed pulleys to carry out a second path that is other than purely radial. As will be understood, the splayed orientation of the arm assemblies allows the substrates 115 to be carried on the first path and the second path that do not overlap.

The first forearm 710, second forearm 713, first wrist member 718, and second wrist member 728 are all received between the vertical locations of the first upper arm 702 and the second upper arm 704. Furthermore, the first upper arm 702, first forearm 710, and first wrist member 718 are all arranged below the locations of the second upper arm 704, second forearm 713, and second wrist member 728, so that interference is avoided for all rotational conditions.

In one or more embodiments, the first upper arm 702 and the first forearm 710 may be of unequal lengths. For example, a length L21 between the shoulder axis 706 and the second axis 712 on the first upper arm 702 may be greater than a length L22 between the second axis 712 and the fourth axis 720 on the first forearm 710.

The second upper arm 704 and second forearm 714 may also be of unequal lengths. For example, a length L23 between the shoulder axis 706 and the third axis 716 on the second upper arm 704 may be greater than a length L24 between the third axis 716 and the fifth axis 730 on the second forearm 714. In some embodiments, the lengths L21 and L23 of the first upper arm 702 and the second upper arm 704 may be between about 110% and 200% greater than the lengths L22 and L24 of the first forearm 710 and second forearm 714, respectively. In one or more embodiments, the lengths L21 and L23 of the first upper arm 702 and the second upper arm 704 may be between about 200 mm and about 380 mm. The lengths L22 and L24 of the first forearm 710 and the second forearm 714 may be between about 100 mm and 345 mm.

The second forearm 714 may be a mirror image of the first forearm 710. In the depicted embodiment, the first forearm 710 may include a first wrist member drive assembly. The first wrist member drive assembly includes a first wrist member driving member, which comprises a cam surface and a first wrist member driven member connected by a first wrist member transmission element made up of multiple belts. The first wrist member driving member may be an oblong pulley including a cam surface. The first wrist member driving member may be rigidly coupled to the first upper arm 702, such as by a shaft or by direct connection. Other types of rigid connections may be used. Likewise, the first wrist member driven member may be an oblong pulley including a cam surface and may be rigidly connected to the first wrist member 718.

In some embodiments, the robot apparatus 700 may include additional wrist members and end effectors to provide for the ability to transport additional substrates. For example, the robot apparatus may include a third wrist member that is rotatable relative to the first forearm member 710 about the first wrist axis 702. A fifth end effector and a sixth end effector may be attached to a distal end of the third wrist member. The fifth end effector may be positioned above the sixth end effector. The robot apparatus may additionally include a fourth wrist member rotatable relative to the second forearm member 713 about the second wrist axis 730. A seventh end effector and an eighth end effector may be attached to a distal end of the fourth wrist member. The seventh end effector may be positioned above the eight end effector. The third and fourth wrist members may be independently rotatable about the first and second wrist axis, respectively.

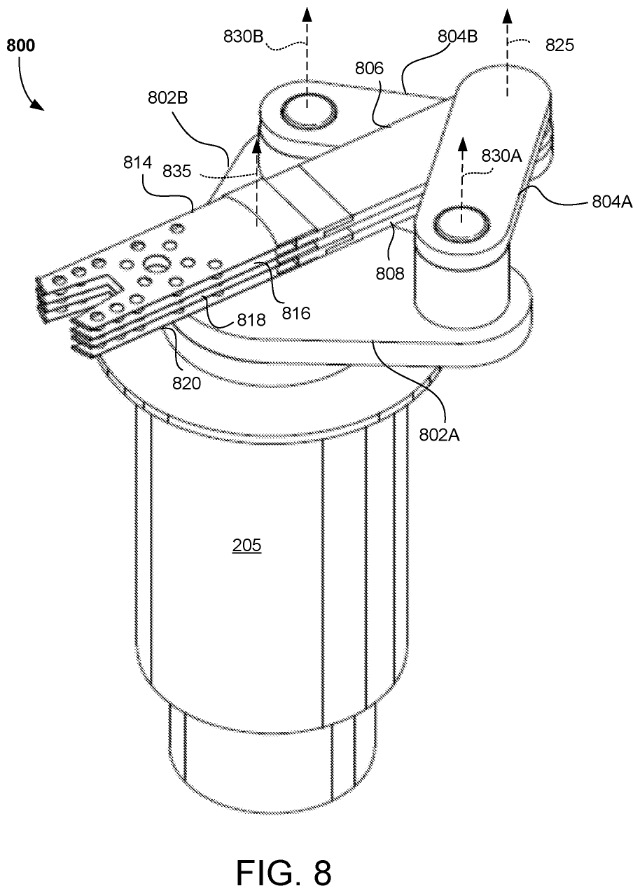

FIG. 8 depicts another example of a robot apparatus 800 with multi-finger end effectors (e.g., vertically stacked end effectors). The robot apparatus 800 includes a first upper arm 802A and a second upper arm 802B, each rotatable about a shoulder axis 835. A first forearm 804A is attached to the first upper arm 802A and is rotatable about a forearm axis 830A, offset from the shoulder axis 835. A second forearm 804B is attached to the second upper arm 802B and is rotatable about a forearm axis 830B, offset from the shoulder axis 835. Attached to the first forearm 804A is a wrist member 806, rotatable about axis 825 which is offset from forearm axis 830A. Attached to the second forearm 830B is a second wrist member 808 which is rotatable about axis 825 with respect to the second forearm 804B.

Multiple end effectors are attached at the distal ends of each wrist member 806 and 808. End effectors 814 and 816 are attached to wrist member 806, and end effectors 818 and 820 are attached to wrist member 808. The wrist members 806 and 808 may be independently extended in a straight line from the position depicted in FIG. 8. Although only two end effectors are depicted as attached to each wrist member, any number of end effectors may be attached to the wrist members.

In some embodiments, the first arm and first forearm are configured to extend the first wrist from a first position to a second position, and the second arm and the second forearm are configured to extend the second wrist in a straight line from a third position to a fourth position, wherein the first position is directly above the third position and the second position is directly above the fourth position.

In the illustrated examples, multiple different blades are shown, each having vertically stacked end effectors, where an upper end effector is directly above a lower end effector, with a fixed relative position between the upper end effector and the lower end effector. In each of the examples, the tips of the upper end effectors line up vertically with (e.g., have the same x and y positions as) the lower end effectors. However, in some instances this may introduce problems in using a local center finder to find a center of a substrate. For example, if an upper end effector and a lower end effector each hold a substrate, and one of the substrates is misaligned on an end effector, it may be difficult to determine whether it is the substrate on the upper end effector or the substrate on the lower end effector that is misaligned. Determining misalignment may be performed to ensure the substrates are placed on center in a receiving station (i.e. in a process chamber) and facilitate process uniformity. Accordingly, in some embodiments the x position and/or the y position of the upper end effector is offset from the x position and/or y position of the lower end effector. For example, the upper end effector may extend further from the robot arm, forearm or wrist that the blade is attached to than the lower end effector. Alternatively, the lower end effector may extend further than the upper end effector. This may enable separate detection of misplacement of the substrate on the upper end effector and the substrate on the lower end effector. Similarly, if one end effector is laterally displaced from the other end effector on a blade (e.g., in a direction that is perpendicular to a longitudinal axis of the blade), then this displacement may enable a laser local center finder to separately identify misalignment of the substrate on the upper end effector and the substrate on the lower end effector. Additional methods may be used to detect the local center as well. For example, the local center can be found using computer vision, embedded sensors on the wrists and/or blades, remote centering within the process module, etc.

In one embodiment, a method of transporting substrates by a robot apparatus includes retrieving, by a first blade comprising a first end effector and a second end effector that is beneath the first end effector and has a fixed position relative to the first end effector, a first substrate on the first end effector, wherein the first blade is attached to the robot apparatus. The method further includes retrieving, by the first blade, a second substrate on the second end effector. The first blade places the first substrate from the first end effector into a process chamber, and the first blade places the second substrate from the first end effector into the process chamber. In a further embodiment, the method includes retrieving, by a second blade comprising a third end effector and a fourth end effector that is beneath the third end effector and has a fixed position relative to the third end effector, a third substrate on the third end effector, wherein the second blade is attached to the robot apparatus. The method further includes retrieving, by the second blade, a fourth substrate on the fourth end effector. The second blade places the third substrate from the third end effector into the process chamber, and the second blade places the fourth substrate from the fourth end effector into the process chamber. Accordingly, two blades may place four substrates into a process chamber. Additionally, in a further embodiment the method includes retrieving four processed substrates from the process chamber by at least two of the first blade, the second blade, or a third blade comprising a fifth end effector and a sixth end effector that is beneath the fifth end effector and has a fixed position relative to the fifth end effector, wherein the third blade is attached to the robot apparatus. These four processed wafers may then be placed in a load lock or another process chamber.

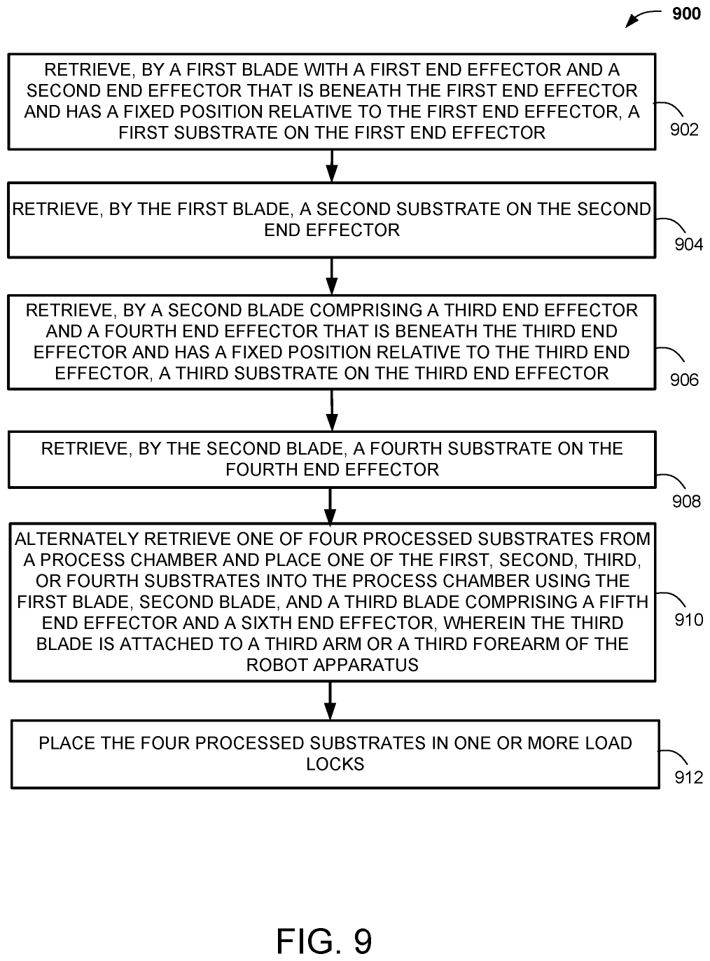

Referring now to FIG. 9, a method 900 of transporting substrates 115 to and from processing chambers 103 is described. Method 900 may be performed using a robot apparatus that includes multiple blades. The multiple blades include a first blade that includes a first end effector and a second end effector positioned beneath the first end effector and having a fixed position relative to the first end effector. The multiple blades further include a second blade that includes a third end effector and a fourth end effector positioned beneath the first end effector and having a fixed position relative to the third end effector. The multiple blades further include a third blade that includes a fifth end effector and a sixth end effector positioned beneath the fifth end effector and having a fixed position relative to the fifth end effector. The robot apparatus of method 900 may be any of the robot apparatuses described in embodiments above for example.

The method 900 includes, in block 902, retrieving, by the first blade, a first substrate on the first end effector. The first blade may be attached to a first arm or a first forearm of the robot apparatus. The method 900 includes, at block 904, retrieving, by the first blade, a second substrate on the second end effector of the first blade.

The method 900 includes, in block 906, retrieving, by the second blade, a third substrate on the third end effector. The second blade may be attached to a second arm or a second forearm of the robot apparatus. The method 900 includes, in block 908, retrieving, by the second blade, a fourth substrate on the fourth end effector. In one embodiment, the first and third end effectors concurrently retrieve the first and third substrates (e.g., via a dual GET process), and the second and fourth end effectors concurrently retrieve the second and fourth substrates (e.g., via a dual GET process). Alternatively, the first and second end effectors may concurrently retrieve the first and second substrates (e.g., via a dual GET process), and the third and fourth end effectors may concurrently retrieve the third and fourth substrates (e.g., via a dual GET process).

The method 900 includes, in block 910, alternately retrieving one of four processed substrates from a processor chamber and placing one of the first, second, third, or fourth substrates into the process chamber using the first blade, the second blade, and the third blade. In one embodiment, the operations of block 910 include the following, optionally in the disclosed sequence:
retrieve a first processed substrate from process chamber by fifth end effector, place the second substrate in the processing chamber by the second end effector; retrieve a second processed substrate from the processing chamber by the sixth end effector;
place the first substrate in the processing chamber by the first end effector;
retrieve a third processed substrate from a processing chamber by the first end effector;
place the fourth substrate in the processing chamber by the fourth end effector;
retrieve a fourth processed substrate from the processing chamber by the second end effector; and
place the third substrate in the processing chamber by the third end effector.

As a result of the retrieving and the placing, the first, second, third, and fourth substrate are placed in the process chamber, the fifth and sixth end effector each hold one of the four processed substrates, and either the first and second end effector each hold one of the four processed substrates or the third and fourth end effector each hold one of the four processed substrates.

After the processed substrates have been removed from the process chamber and are held on the end effectors, they may be placed into a load lock or other process chamber. In one embodiment, the fifth end effector places a first processed substrate into a first load lock and the sixth end effector concurrently places a second processed substrate into the first load lock (e.g., via a dual PUT process). The first end effector may place a third processed substrate into the first load lock or a second load lock, and the second end effector may concurrently place a fourth processed substrate into the first load lock or the second load lock (e.g., via a dual PUT process). Alternatively, if the third and fourth end effectors retrieved the third and fourth processed substrates, then the third end effector may place the third processed substrate into the first or second load lock, and the fourth end effector may concurrently place the fourth processed substrate into the first or second load lock (e.g., via a dual PUT process).

The foregoing description discloses only certain example embodiments. For example, certain example embodiments describe two stacked end effectors. Modifications of the above-disclosed systems, apparatus, and methods which fall within the scope of the disclosure will be readily apparent to those of ordinary skill in the art. For example, embodiments discussed with reference to two stacked end effectors also apply to three, four or more stacked end effectors. Additionally, embodiments are not limited to the robots, process chamber architectures or transfer chamber architectures illustrated and described herein. Accordingly, while the present disclosure has been disclosed in connection with certain example embodiments, it should be understood that other embodiments may fall within the scope of the disclosure, as defined by the following claims.

What is claimed is:

1. A robot apparatus, comprising:
a first arm comprising an inboard end attached to a drive motor assembly for rotation about a first shoulder axis;
a first wrist, a second wrist and a third wrist each attached to an outboard end of the first arm for rotation relative to the first arm about an outboard axis;
a first end effector attached to a distal end of the first wrist, and a second end effector attached to the distal end of the first wrist below the first end effector, wherein each of the first and second end effectors is attached to the first wrist at a fixed position relative to the first wrist;
a third end effector attached to a distal end of the second wrist, and a fourth end effector attached to the distal end of the second wrist below the third end effector, wherein each of the third and fourth end effectors is attached to the second wrist at a fixed position relative to the second wrist and
a fifth end effector attached to a distal end of the third wrist and a sixth end effector attached to the distal end of the third wrist below the fifth end effector, wherein each of the fifth and sixth end effectors is attached to the third wrist at a fixed position relative to the second wrist.

2. (canceled)

3. The robot apparatus of claim 1, wherein the first end effector comprises a first substrate support location having a first nominal center and the second end effector comprises a second substrate support location having a second nominal center, wherein the first nominal center and the second nominal center are aligned along a vertical axis.

4. (canceled)

5. (canceled)

6. The robot apparatus of claim 1, wherein the first, second and third wrists are each independently rotatable about the outboard axis.

7. The robot apparatus of claim 1, further comprising:
a second arm rotatable about the first shoulder axis;
a second forearm rotatable relative to the second arm about a second forearm axis at a position offset from the first shoulder axis;
a third end effector attached to a distal end of the second forearm; and
a fourth end effector attached to the distal end of the second forearm, wherein the third end effector is positioned above the fourth end effector.

8. The robot apparatus of claim 7, wherein the first and second arms are each independently rotatable about the first shoulder axis.

9. A robot apparatus, comprising:
a first arm rotatable about a first shoulder axis;
a first forearm rotatable relative to the first arm about a first forearm axis at a position offset from the first shoulder axis;
a first wrist rotatable relative to the first forearm about a first wrist axis at a position offset from the first forearm axis;
a first end effector attached to a distal end of the first wrist; and
a second end effector attached to the distal end of the first wrist, wherein the first end effector is positioned above the second end effector, wherein the second end effector has a fixed position relative to the first end effector such that the first end effector and the second end effector are movable in unison.

10. The robot apparatus of claim 9, further comprising
a second arm rotatable about the first shoulder axis;
a second forearm rotatable relative to the second arm about a second forearm axis at a position offset from the first shoulder axis;
a second wrist rotatable relative to the second forearm about a second wrist axis at a position offset from the second forearm axis, wherein the first wrist is configured to extend in a straight line from a retracted position and the second wrist is configured to extend in a straight line from a retracted position directly above the first wrist;
a third end effector attached to a distal end of the first wrist; and
a fourth end effector attached to the distal end of the first wrist, wherein the first end effector is positioned above the second end effector, wherein the second end effector has a fixed position relative to the first end effector such that the first end effector and the second end effector are movable in unison.

11. The robot apparatus of claim 9, wherein the first end effector comprises a first substrate support location having a first nominal center and the second end effector comprises a second substrate support location having a second nominal center, wherein the first nominal center and the second nominal center are aligned along a vertical axis.

12. The robot apparatus of claim 9, further comprising:
a second wrist rotatable relative to the first forearm about the first wrist axis;
a third end effector attached to a distal end of the second wrist;
a fourth end effector attached to the distal end of the second wrist, wherein the third end effector is positioned above the fourth end effector;
wherein the first wrist and the second wrist are configured to rotate about the first wrist axis to provide for a first distance between the distal end of the first wrist and the distal end of the second wrist while extended a first distance from the shoulder axis; and
wherein the first wrist and the second wrist are configured to rotate about the first wrist axis to a second distance between the distal end of the first wrist and the distal end of the second wrist while extended a second distance from the first shoulder axis.

13. The robot apparatus of claim 9, further comprising:
a second wrist rotatable relative to the first forearm about the first wrist axis;
a third end effector attached to the distal end of the second wrist; and
a fourth end effector attached to the distal end the second wrist, wherein the third end effector is positioned above the fourth end effector.

14. The robot apparatus of claim 13, further comprising:
a third wrist rotatable relative to the first forearm about the first wrist axis;
a fifth end effector attached to a distal end of the third wrist; and
a sixth end effector attached to the distal end of the third wrist, wherein the fifth end effector is positioned above the sixth end effector.

15. The robot apparatus of claim 9, further comprising:
a second arm rotatable about the first shoulder axis;
a second forearm rotatable relative to the second arm about a second forearm axis at a position offset from the first shoulder axis;
a second wrist rotatable relative to the second forearm about a second wrist axis at a position offset from the first forearm axis;
a third end effector attached to a distal end of the second wrist; and
a fourth end effector attached to the distal end of the second wrist, wherein the third end effector is positioned above the fourth end effector.

16. The robot apparatus of claim 15, wherein the first arm and first forearm are configured to extend the first wrist from a first position to a second position, and the second arm and the second forearm are configured to extend the second wrist in a straight line from a third position to a fourth position, wherein the first position is directly above the third position and the second position is directly above the fourth position.

17. A method of transporting substrates by a robot apparatus, comprising:
for a robot apparatus comprising:
a first arm comprising an inboard end attached to a drive motor assembly for rotation about a first shoulder axis
a first wrist, a second wrist and a third wrist each attached to an outboard end of the first arm for rotation relative to the first arm about an outboard axis;
a first end effector attached to a distal end of the first wrist, and a second end effector attached to the distal end of the first wrist below the first end effector, wherein each of the first and second end effectors is attached to the first wrist at a fixed position relative to the first wrist
a third end effector attached to a distal end of the second wrist, and a fourth end effector attached to the distal end of the second wrist below the third end effector, wherein each of the second third and fourth end effectors is attached to the second wrist at a fixed position relative to the second wrist and
a fifth end effector attached to a distal end of the third wrist and a sixth end effector attached to the distal end of the third wrist below the fifth end effector, wherein each of the fifth and sixth end effectors is attached to the third wrist at a fixed position relative to the second wrist:
retrieving, by a first blade comprising the first end effector and the second end effector, a first substrate on the first end effector, wherein the first blade is attached to the robot apparatus;
retrieving, by the first blade, a second substrate on the second end effector;
placing, by the first blade, the first substrate from the first end effector into a process chamber; and
placing, by the first blade, the second substrate from the first second end effector into the process chamber.

18. The method of claim 17, further comprising:
retrieving, by a second blade comprising the third end effector and the fourth end effector, a third substrate on the third end effector, wherein the second blade is attached to the robot apparatus;
retrieving, by the second blade, a fourth substrate on the fourth end effector;
placing, by the second blade, the third substrate from the third end effector into the process chamber;
placing, by the second blade, the fourth substrate from the fourth end effector into the process chamber; and
retrieving four processed substrates from the process chamber by at least two of the first blade, the second blade, or a third blade comprising the fifth end effector and the sixth end effector, wherein the third blade is attached to the robot apparatus.

19. The method of claim 18, further comprising:
alternately performing the retrieving of one of four processed substrates from the process chamber and the placing one of the first substrate, the second substrate, the third substrate, or the fourth substrate into the process chamber using the first blade, the second blade, and the third blade, wherein as a result of the retrieving and the placing:
the fifth end effector and the sixth end effector each hold one of the four processed substrates; and
one of a) the first end effector and the second end effector each hold one of the four processed substrates, orb) the third end effector and the fourth end effector each hold one of the four processed substrates.

20. The method of claim 19, further comprising:
concurrently placing a first processed substrate into a first load lock and a second processed substrate into the first load lock by the fifth end effector and the sixth end effector, respectively; and
one of a) concurrently placing a third processed substrate into a second load lock by the first end effector and a fourth processed substrate into the second load lock by the second end effector, respectively, or b) concurrently placing the third processed substrate into the second load lock by the third end effector and the fourth processed substrate into the second load lock by the fourth end effector, respectively.

21. The method of claim 19, wherein alternately performing the retrieving of one of the four processed substrates from the process chamber and the placing of one of the first substrate, the second substrate, the third substrate, or the fourth substrate into the process chamber using the first blade, the second blade, and the third blade comprises:
retrieving a first processed substrate from the process chamber by the fifth end effector;
subsequently performing the placing of the second substrate in the processing chamber by the second end effector;
retrieving a second processed substrate from the processing chamber by the sixth end effector;
subsequently performing the placing of the first substrate in the processing chamber by the first end effector;
retrieving a third processed substrate from a processing chamber by the first end effector;
subsequently performing the placing of the fourth substrate in the processing chamber by the fourth end effector;
retrieving a fourth processed substrate from the processing chamber by the second end effector; and
subsequently performing the placing of the third substrate in the processing chamber by the third end effector.

22. The method of claim 18, wherein:
retrieval of the first substrate by the first end effector and retrieval of the third substrate by third end effector is performed concurrently; and
retrieval of the second substrate by the second end effector and retrieval of the fourth substrate by the fourth end effector is performed concurrently.

23. A blade for a robot arm, the blade comprising:
a first end effector attached to a distal end of the blade, wherein the first end effector is attached to the blade at a fixed position relative to the blade; and
a second end effector attached to the distal end of the blade, wherein the second end effector is attached to the blade at a fixed position below the first end effector.

24. The method of claim 17, wherein the first end effector comprises a first substrate support location having a first nominal center and the second end effector comprises a second substrate support location having a second nominal center, wherein the first nominal center and the second nominal center are aligned along a vertical axis.

25. The method of claim 17, wherein the first, second and third wrists are each independently rotatable about the outboard axis.
